(19) United States
(12) Patent Application Publication
(10) Pub. No.: US 2024/0006267 A1
(43) Pub. Date: Jan. 4, 2024

(54) Hermetic Package Cooling Using Silver Tubes with Getter Absorption Material

(71) Applicant: Texas Instruments Incorporated, Dallas, TX (US)

(72) Inventors: Li Jiang, Allen, TX (US); Yiqi Tang, Allen, TX (US); Jie Chen, Plano, TX (US); Rajen M. Murugan, Dallas, TX (US)

(21) Appl. No.: 17/809,808

(22) Filed: Jun. 29, 2022

(51) Int. Cl. H01L 23/433; H01L 23/15; H01L 23/13; H01L 21/48

(52) U.S. Cl. CPC H01L 23/433; H01L 23/15; H01L 23/13; H01L 21/4882; H01L 24/16

(57) ABSTRACT

An example semiconductor package comprises a ceramic header having a top surface and a cavity formed within the ceramic header. The cavity is open at the top surface. A semiconductor die is mounted within the cavity of the ceramic header. A lid structure is coupled to the top surface of the ceramic header. The lid structure and ceramic header form a portion of a package enclosing the semiconductor die. One or more silver tubes are in contact with a first surface of the semiconductor die and with a first surface of the lid structure. A seal ring is located between the top surface of the ceramic header and the lid structure. The seal ring couples the lid structure to the ceramic header. The one or more silver tubes are hollow and filled with a getter material.

### BACKGROUND

Ceramic hermetic packages are often used in military and space applications for sensitive parts that have a need for physical and atmospheric protection. Sensitive devices can be surrounded by a housing or package that shields the device against ambient and electrical disturbances and against stress. For many devices, fully hermetic packages represent a significant cost, especially when ceramic packages or precision parts are required. Moisture content in ceramic hermetic packages can be evaluated using Residual Gas Analysis (RGA). Moisture content above 5,000 ppmv within the sealed package is typically considered a failure mode. Sealed ceramic hermetic packages may fail for thermal performance if an embedded silicon device does not sufficiently transfer heat to the ceramic package. Control of moisture and heat transfer can be difficult to manage within a sealed hermetic package.

### SUMMARY

In an arrangement, a semiconductor package comprises a ceramic header having a top surface and a cavity formed within the ceramic header, the cavity open at the top surface. A semiconductor die is mounted within the cavity of the ceramic header. A lid structure is coupled to the top surface of the ceramic header. The lid structure and ceramic header form a portion of a package enclosing the semiconductor die. One or more silver tubes are in contact with a first surface of the semiconductor die and with a first surface of the lid structure. A seal ring is located between the top surface of the ceramic header and the lid structure. The seal ring couples the lid structure to the ceramic header. The one or more silver tubes are hollow and filled with a getter material.

The semiconductor package further comprises a first layer of nano-scale silver material bonded between the one or more silver tubes and the first surface of the lid structure, and a second layer of nano-scale silver material bonded between the one or more silver tubes and the first surface of the semiconductor die. The nano-scale silver material is bonded by sintering.

The ceramic header may comprise a multi-layer substrate having a plurality of conductive traces coupling landing pads on an interior surface of the cavity to conductive pads on a bottom surface of the ceramic header. A plurality of solder bumps couple the landing pads to bond pads formed on an active surface of the semiconductor die.

The semiconductor package may further comprise an electroplate metal layer on a second surface of the lid structure.

The semiconductor package may further comprise a seam seal between the lid structure and the ceramic header.

The semiconductor package comprises a first thermal path from the semiconductor die to a bottom surface of the package via solder bumps and the ceramic header and a second thermal path from the semiconductor die to a top surface of the package via the one or more silver tubes and the lid structure.

An example semiconductor package comprises a ceramic header structure having a top surface and a bottom surface. A cavity is formed within the top surface of the ceramic header. A semiconductor device is attached to a mounting surface within the ceramic header cavity. A lid is coupled to the top surface of the ceramic header. The lid and ceramic header are configured to enclose the semiconductor die. One or more hollow silver tubes are in contact with a first surface of the semiconductor device and with a first surface of the lid. A getter material is disposed within the one or more hollow silver tubes. A seal ring is positioned between the top surface of the ceramic header and the lid. The seal ring couples the lid to the ceramic header. A seam seal is formed between the lid and the ceramic header.

The semiconductor package may further comprise a first layer of nano-scale silver material bonded between the one or more silver tubes and the first surface of the lid, and a second layer of nano-scale silver material bonded between the one or more silver tubes and the first surface of the semiconductor device. The first layer of nano-scale silver material and the second layer of nano-scale silver material are bonded by sintering.

The semiconductor package may further comprise a plurality of conductive pads on the bottom surface of the ceramic header and a plurality of solder joints coupling the conductive pads to a first printed circuit board.

The semiconductor package may further comprise an electroplate metal layer on a second surface of the lid structure and a solder joint coupling the electroplate metal layer of the lid structure to a second printed circuit board.

The semiconductor package comprises a first thermal path from the semiconductor device to first printed circuit board via the ceramic header and a second thermal path from the semiconductor die to the second printed circuit board via the one or more silver tubes and the lid structure.

In one arrangement, a method of manufacturing a semiconductor package, comprises providing a ceramic header structure having a top surface, a bottom surface, and a cavity formed within the top surface; attaching a semiconductor die to a mounting surface within the ceramic header cavity; sintering a plurality of silver tubes to a lid structure using a nano-scale silver material; attaching the lid structure to the top surface of the ceramic header so that the plurality of silver tubes contact a surface of the semiconductor die; and sintering the silver tubes to the semiconductor die surface.

The method may further comprise attaching the lid structure to the top surface of the ceramic header using a seal ring.

The plurality of silver tubes may be hollow and filled with a getter material.

The semiconductor die may be flip-chip mounted within the ceramic header cavity.

### BRIEF DESCRIPTION OF THE DRAWINGS

Having thus described the invention in general terms, reference will now be made to the accompanying drawings, wherein:

FIG. 1 is a cross section view of a ceramic flip-chip hermetic package according to one arrangement.

FIGS. 2A-H are a series of a cross section views that illustrate a process for assembling a hermetic package having dual-sided-cooling using silver tubes with a getter fill to absorb moisture.

FIG. 3 is a cross section view of a system using a hermetic ceramic package as described for some arrangements.

FIG. 4 is a flowchart illustrating an example process for assembling a hermetic ceramic package with dual-sided cooling using silver tubes with getter material to absorb moisture.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

Corresponding numerals and symbols in the different figures generally refer to corresponding parts, unless otherwise indicated. The figures are not necessarily drawn to scale. In the drawings, like reference numerals refer to like elements throughout, and the various features are not necessarily drawn to scale. In the following discussion and in the claims, the terms “including,” “includes,” “having,” “has,” “with,” or variants thereof are intended to be inclusive in a manner similar to the term “comprising,” and thus should be interpreted to mean “including, but not limited to . . . ” Also, the terms “coupled,” “couple,” and/or or “couples” is/are intended to include indirect or direct electrical or mechanical connection or combinations thereof. For example, if a first device couples to or is electrically coupled with a second device that connection may be through a direct electrical connection, or through an indirect electrical connection via one or more intervening devices and/or connections. Elements that are electrically connected with intervening wires or other conductors are considered to be coupled. Terms such as “top,” “bottom,” “front,” “back,” “over,” “above,” “under,” “below,” and such, may be used in this disclosure. These terms should not be construed as limiting the position or orientation of a structure or element but should be used to provide spatial relationship between structures or elements.

The term “semiconductor die” is used herein. A semiconductor device can be a discrete semiconductor device such as a bipolar transistor, a few discrete devices such as a pair of power FET switches fabricated together on a single semiconductor die, or a semiconductor die can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, for example a microprocessor or memory device. The semiconductor device may also be referred to herein as a semiconductor device or an integrated circuit (IC) die.

The term “semiconductor package” is used herein. A semiconductor package has at least one semiconductor die electrically coupled to terminals and has a package body that protects and covers the semiconductor die. In some arrangements, multiple semiconductor dies can be packaged together. For example, a power metal oxide semiconductor (MOS) field effect transistor (FET) semiconductor device and a second semiconductor device (such as a gate driver die, or a controller die) can be packaged together to from a single packaged electronic device. Additional components such as passive components, such as capacitors, resistors, and inductors or coils, can be included in the packaged electronic device. The semiconductor die is mounted with a package substrate that provides conductive leads. A portion of the conductive leads form the terminals for the packaged device. In wire bonded integrated circuit packages, bond wires couple conductive leads of a package substrate to bond pads on the semiconductor die. The semiconductor die can be mounted to the package substrate with a device side surface facing away from the substrate and a backside surface facing and mounted to a die pad of the package substrate. The semiconductor package can have a package body formed by a thermoset epoxy resin mold compound in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions form the terminals for the semiconductor package. The semiconductor package may also be referred to as a “integrated circuit package,” a “microelectronic device package,” or a “semiconductor device package.”

The term “ceramic header” is used herein. A ceramic header in a completed semiconductor device package includes a mounting portion configured to provide a mounting surface for an electronic device. Ceramic headers useful with the arrangements can be formed from aluminum oxide or aluminum nitride. The ceramic header can include a bond pad surface for mounting a semiconductor die. Conductive leads couple bond pads on the semiconductor die to contacts on the outside surface of the ceramic header. More than one semiconductor die can be mounted to ceramic header.

The term “getter material” is used herein. A getter material is designed to react with gases in a confined atmosphere. The getter material is used to maintain a desired hermeticity level for a sealed package in typical uses. Gases that may remain within a sealed cavity include, for example, carbon monoxide (CO), carbon dioxide (CO2), nitrogen (N2), hydrogen (H2), and water vapor (H2O). The getter material may act by adsorption, absorption, or chemical binding to remove such gases from the atmosphere. Common getter materials include, for example, Aluminum (Al), Barium (Ba), Magnesium (Mg), Titanium (Ti), (Cerium (Ce),

Lanthanum (La), other rare earth elements.

The term “silver tube” is used herein. A silver tube is a hollow, elongated cylinder. The length dimension of the tube is typically much longer compared to a width or thickness dimension; however, relatively short silver tubes may also be used with arrangements disclosed herein. The silver tube is made of silver (Ag) metal or a silver alloy, such as silver-copper (Ag—Cu), silver-tin (Ag—Sn), or silver-zinc (Ag—Zn), with a high thermal conductivity. The hollow center of the cylinder is exposed by openings on the end of the tube. Materials, such as getter materials, may be placed in the hollow center and are exposed to the atmosphere near the silver tube via the tube-end openings.

The term “nano-scale silver material” or “nano-scale silver paste” is used herein. A nano-scale silver material is formed of nanoparticles of silver (Ag) that are generally between 1 nm and 100 nm in size. The nanoparticles may be a mix of both silver and silver oxide (Ag2O) some are composed of a large percentage of silver oxide. The silver material may be in a powder or paste form that is readily used in fabricating sintered joints and for bonding and curing at relatively low temperatures in the range of 200-300° C.

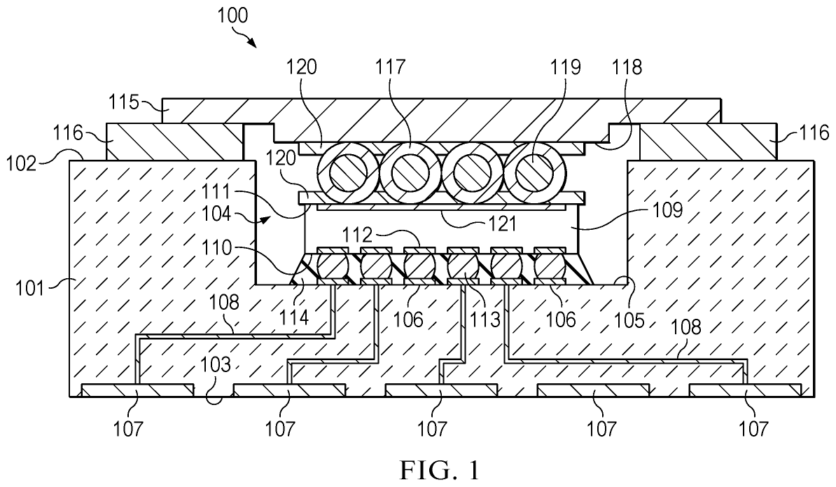

FIG. 1 is a cross section view of a ceramic flip-chip hermetic package 100. A ceramic header 101 has top surface 102 and a bottom surface 103. An open interior cavity 104 is formed within the top surface 102 of the ceramic header 101. The interior cavity 104 has an interior mounting surface 105. A number of landing pads 106 are formed on the interior surface 105. A number of conductive pads 107 are formed on the bottom surface 103 of the ceramic header 101. Individual ones of the landing pads 106 on the interior surface 102 are coupled to conductive pads 107 on the exterior surface 103 by conductive traces 108 through ceramic header 101. In the illustrated example, ceramic header 101 forms at least a portion of a hermetic seal. Ceramic header 101 may comprise any suitable ceramic material used in electronic device packaging, such as a material comprising at least 90% aluminum oxide. Ceramic header 101 may further include a plurality of confronting ceramic layers (not shown) that form metallized or conductive traces 108 within a solid monolithic geometric form.

A semiconductor device, such as an integrated circuit (IC) die 109, is mounted within the interior cavity 104 of ceramic header 101. In some arrangements, IC die 109 may be a Flip-Chip Ball Grid Array (FCBGA) device. IC die 109 may include one or more electronic devices. In various embodiments, IC die 109 can include micro-scale and/or nano-scale moving parts. For example, IC die 109 may include accelerometers, gyroscopes, and pressure sensors. IC die 109 has a first surface 110 and a second surface 111. A number of bond pads 112 are formed on first surface 110. Solder bumps 113 join each bond pad 112 to a landing pad 106. Solder bumps 113 may be made from various conductive materials. Solder bumps 113 enable electrical connections between IC die 109 and various external components via bond pads 112, landing pads 106, conductive paths 108, and conductive pads 107. An underfill 114 is deposited between first surface 110 of IC die 109 and interior surface 105 of ceramic header 101.

The open interior cavity 104 of ceramic header 101 is sealed using a lid 115 that is in direct contact with top surface 102 or with a seal ring 116 that may be disposed between lid 115 and top surface 102. The material forming lid 115 may be a moisture-impenetrable material such as glass, ceramic, or metal to provide a fully hermetic sealing over ceramic header 101. Seal ring 116 may be, for example, solder or a low-melting gold or copper alloy to allow complete sealing, such as a solder preform comprising 80% gold and 20% tin. The interior cavity 104 may be hermetically sealed when the lid 115 is attached by an airtight and watertight seal to ceramic header 101.

A plurality of hollow silver (Ag) tubes 117 are positioned between the second surface 111 of IC die 109 and an inside surface 118 of lid 115. The silver tubes 117 functions as carriers for a getter material 119 within the hollow interior of tubes 117. The getter material is designed to react with gas species present within interior cavity 104 when lid 115 is sealed onto ceramic header 101. The getter material is used to maintain a desired hermeticity level for the ceramic flip-chip hermetic package 100. The getter material 119 may act by adsorption, absorption, or chemical binding.

The silver tubes 117 may be attached to the second surface 111 of IC die 109 and to the inside surface 118 of lid 115 using a nano-scale silver paste 120. The thermal, electrical, and mechanical properties of nano-scale silver paste 120 provide superior heat transfer from IC die 109 to lid 115. The second surface 111 of IC die 109 may include a metallization layer 121 to ensure conductive bonding of the nano-scale silver paste 120 to IC die 109.

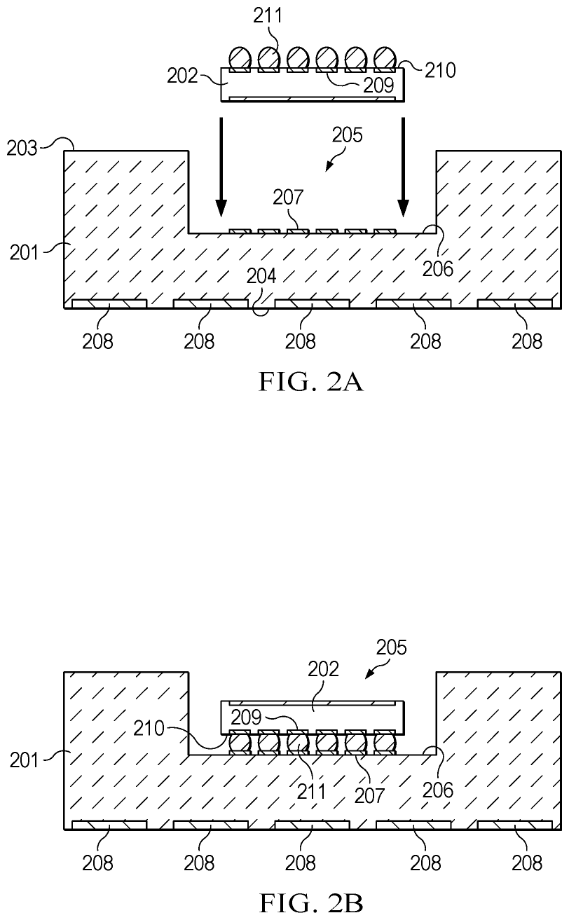

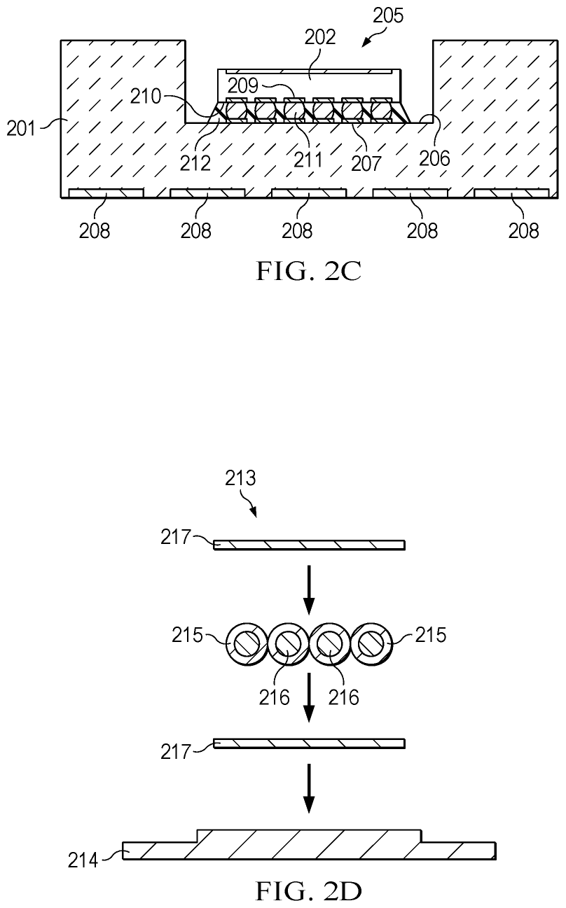

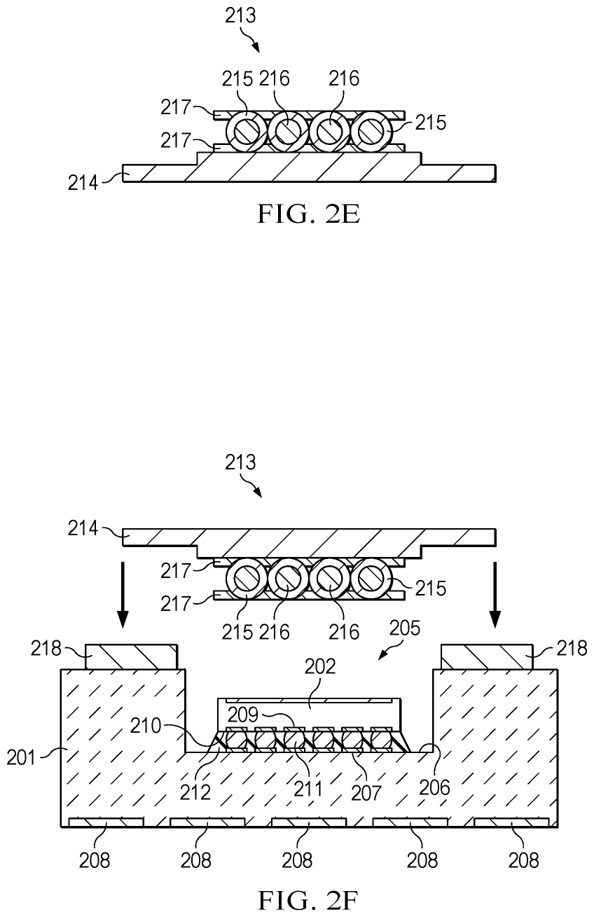

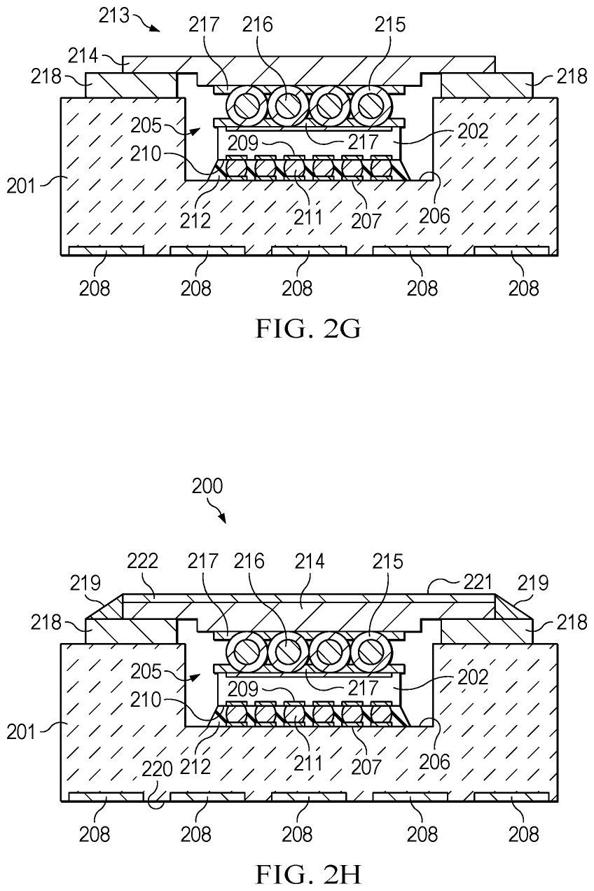

FIGS. 2A-H are a series of a cross section views that illustrate a process for assembling a hermetic package having dual-sided-cooling using silver tubes with a getter fill to absorb moisture.

FIG. 2A illustrates preparation of a ceramic header 201 and an IC die 202. Ceramic header 201 has top surface 203 and a bottom surface 204. An open interior cavity 205 is formed within the top surface 203 of the ceramic header 201. The interior cavity 205 has an interior mounting surface 206. The ceramic header 201 may have multiple layers in one arrangement. Ceramic tape layers may be metalized, laminated, and fired to create header 201. Conductive paths (not shown) may be formed in the ceramic header 201 between a number of landing pads 207 formed on the interior mounting surface 206 and conductive pads 208 are formed on the bottom surface 204. Header 201 may be formed using an Alumina (Al2O3) or Aluminum Nitride (AlN) ceramic material in some examples.

IC die 202 may be any device that requires a gastight or watertight operating environment, such as micro-electromechanical systems (MEMS) devices used in military, aerospace, and high performance commercial applications. IC die 202 has a number of bond pads 209 on an active surface 210. Conductive bumps 211 are placed directly on the bond pads 209 during wafer processing. In one arrangement, conductive bumps are formed from lead (Pb) solder.

FIG. 2B illustrates mounting of the IC die 202 to the ceramic header 201. During assembly, the bumped IC die 202 is flipped and placed so that active surface 210 faces down. The bumps 211 then contact landing pads 207 on the interior mounting surface 206 of ceramic header 201. The bumps 211 are reflowed to bond IC die 202 and ceramic header 201 together.

FIG. 2C illustrates an encapsulant or “underfill” 212 that is deposited between interior mounting surface 206 of ceramic header 201 and the active surface 210 of IC die 202. The gap between interior mounting surface 206 and active surface 210 is filled with a polymeric encapsulant 212 that extends over surface 206 about the perimeter of the IC die 202. The underfill 212 reduces mechanical stress in the assembly. Additionally, underfill 212 protects the active chip surface 210. The underfill 212 is typically applied after the solder bumps 211 are reflowed to bond the IC die 202 to the ceramic header 201. Underfill 212 may be a polymeric precursor that is dispensed onto mounting surface 206 adjacent to IC die 202 and is pulled into the gap by capillary forces. The underfill may then be heated, polymerized, and cured to form an encapsulant.

FIG. 2D illustrates preparation of lid components 213 for a hermetic package. A lid 214 may be formed from a moisture-impenetrable material, such as glass, ceramic, or metal. In one arrangement, lid 214 is formed from an iron-nickel-cobalt (FeNiCo) alloy, which may be referred to as “KOVAR.” The lid 214 is configured to provide a fully hermetic seal over opening 205 of ceramic header 201. Lid components 213 further include a plurality of silver (Ag) tubes 215. Silver tubes 215 have a hollow center that is filled with a getter material 216. The getter material 216 is designed to react with gases that may be present within interior cavity 205 when lid 213 is sealed onto ceramic header 201. Typical gases that may remain within interior cavity 205 include carbon monoxide (CO), carbon dioxide (CO2), nitrogen (N2), hydrogen (H2), and water vapor (H2O). Common getter materials 216 include, for example, Aluminum (Al), Barium (Ba), Magnesium (Mg), Titanium (Ti), (Cerium (Ce), Lanthanum (La), other rare earth elements. The getter material 216 may act by adsorption, absorption, or chemical binding. The getter material 216 is used to maintain a desired hermeticity level within a sealed ceramic flip-chip hermetic package.

FIG. 2E illustrates the combination of lid components 213 such as by partial sintering of lid 214, silver tubes 215, and a nano-scale silver paste or film 217. Silver tubes 215 function as carriers for getter material 216.

FIG. 2F illustrates the alignment of the lid components 213 with ceramic header 201 to enclose IC die 202 within cavity 205. A seal ring 218 is positioned around the opening of cavity 205 and is configured to receive lid 214. Lid components 213 are lowered on to seal ring 218. Seal ring 218 may be any suitable material used in semiconductor packaging that forms at least a portion of a hermetic seal, such as, for example, silicon, ceramics, metals, glass, or any combination thereof.

FIG. 2G illustrates IC die 202 begin sealed within the interior cavity 205 of ceramic header 201 using lid components 213. Lid 214 is in direct contact with seal ring 218. Silver tubes 215 are bonded to IC die 202 by sintering of nano-scale silver paste 217. The silver tubes 215 attach to the surface of IC die 201 and to the inside surface of lid 214 using nano-scale silver paste 217. The nano-scale silver paste 217 provides a heat transfer path from IC die 202 to lid 214 via silver tubes 215.

FIG. 2H illustrates a seam seal 219 on lid 214 and seal ring 218. Seam seal 219 may be created using seam welding or laser welding in some arrangements to create a hermetic ceramic flip-chip package 200. By including silver tubes 215 between IC die 202 and lid 214, package 200 is capable of dual-sided cooling both through the bottom side 220 (via solder bumps 211 and ceramic header 201) and through the top side 221 (via silver tubes 215, sintered nano-scale silver paste 217, and lid 214). In some examples, the exposed top of lid 214 will be finished with electrolytic Nickle-Gold (NiAu) 222, which is a layer of gold plated over a base of electroplated nickel, to avoid oxidation and improve the solderability of copper contacts.

Table 1 lists the thermal resistance parameters for an example a hermetic ceramic flip-chip package 200 using silver tubes between the IC die and lid.

TABLE 1

| | | | | |
|---|---|---|---|---|
| | Thermal | | | Thermal |
| | Conductivity | Length | Area | Resistance |
| Materials | (k) | (h) | (s) | (h/k*s) |

Bottom Side of Package:

| | | | | | | |
|---|---|---|---|---|---|---|
| Ceramic Header | 14 | W/(m · K) | 750 um | 24 | mm² | 2.23 |
| (Alumina A440) | | | | | | |
| Solder Bumps | 50.8 | W/(m · K) | 50 um | 0.5 | mm² | 1.97 |
| (Pb) | | | | | | |

| | |
|---|---|
| Total Estimated Bottom-Side Resistance | 4.20 |

Top Side of Package:

| | | | | | | |
|---|---|---|---|---|---|---|
| Lid | 17 | W/(m · K) | 250 um | 13.5 | mm² | 1.09 |
| (Kovar FeNiCo) | | | | | | |
| Silver Tube/ | 429 | W/(m · K) | 260 um | 0.2 | mm² | 3.03 |
| Sintered Silver | | | | | | |
| (Ag) | | | | | | |

| | |
|---|---|
| Total Estimated Top-Side Resistance | 4.12 |

As shown in Table 1, the top side 221 of package 200 may have better thermal dissipation capability (i.e., lower thermal resistance) than the bottom side 220. In other arrangements, the area of the silver tube 217 may increase, such as if the tube was flattened against lid 214 and IC die 202 during attachment of lid 214 to ceramic header 201. This would further lower the thermal resistance on the top side 221 of package 200. Generally, the lid-to-die contact forms a natural clamp that adds pressure for silver sintering. Accordingly, introducing the silver tubes 215 improves the thermal conductivity of a hermetic ceramic package. Table 2 further illustrates the benefit of using silver tubes since silver's thermal conductivity is higher than other likely options.

TABLE 2

| | Thermal Conductivity |
|---|---|
| Material | (W/m · K) |
| Silver (Ag) | 429 |
| Copper (Cu) | 398 |
| Gold (Au) | 315 |
| Aluminum (Al) | 247 |

By filling the silver tubes 215 with a getter material 216, the hermetic ceramic package 200 is further improved by reducing gases and/or moisture that remain inside the package after lid 214 is attached.

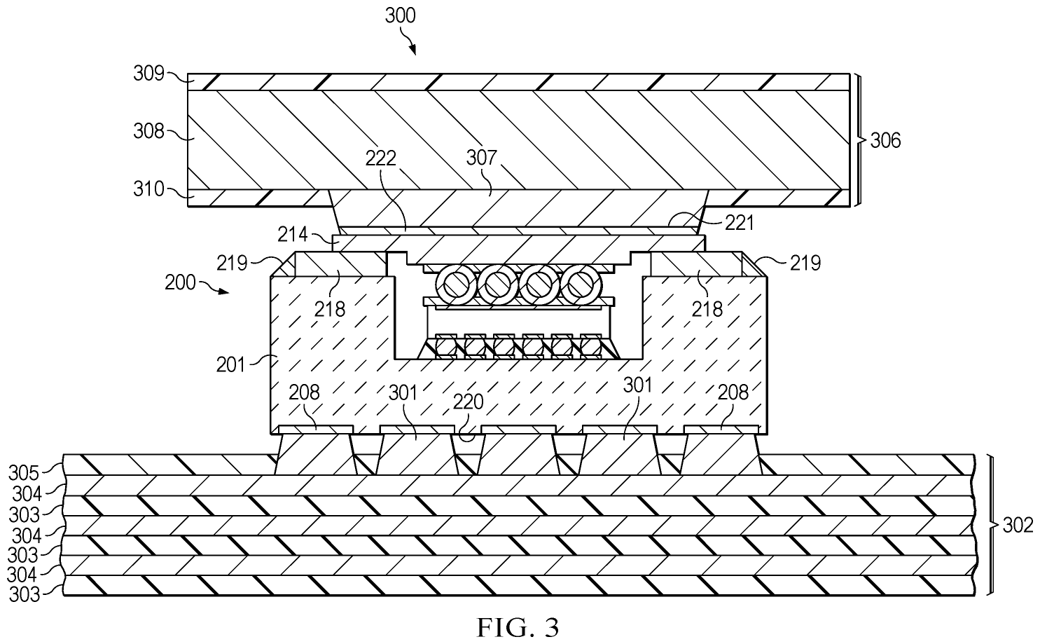

FIG. 3 is a cross section view of a system 300 using hermetic ceramic package 200 as described for some arrangements. Solder joints 301 couple the bottom side 220 of package 200 to a first printed circuit board (PCB) 302 via conductive pads 208. PCB 302 may include layers of insulating material 303, such as a glass epoxy (e.g., FR4), between copper (Cu) layers 304. A solder resist layer 305 may be applied to the top of PCB 302.

The top side 221 of package 200 to a second PCB 306 by solder joint 307. PCB 306 includes a copper (Cu) layer 308 with solder resist layers 309, 310 on the top and bottom sides, respectively. A NiAu finish 311 is applied to lid 214, which allows solder joint 307 to be used instead of thermal interface material (TIM). This is a better configuration than attaching a heatsink with TIM to the top 221 of package 200, which would have a low thermal conductivity. Additionally, this configuration is better than attaching a heatsink to the top 221 of package 200 with solder, which is subject to high thermomechanical stresses due to a large coefficient of thermal expansion (CTE) mismatch with heatsink aluminum (Al). Top solder joint 307 can be patterned for surface-mount technology (SMT) and reliability concerns. The second PCB 306 layout can be determined based on available space, thermal performance, and cost.

System 300 is an improvement upon existing hermetic packages by providing as much as twice the thermal dissipation capability over the original hermetic package. The risk of RGA failure is reduced by including the getter material 216 in package 200. RGA failure can result in months of investigation for root causes and may require scraping of all affected assembly lots. Use of the hollow space in the silver tubes ensures a fixed location to carry the getter material. The using hermetic ceramic package 200 utilizes the standard structure and feature of a hermetic flip-chip package, such as a lid on top of the IC die and a NiAu surface finish. Assembly of package 200 lowers the threshold capability required for assembly of the device to achieve duel-sided cooling. Such assembly can be applied to all flip-chip hermetic packages. This solution may also be applied to multi-chip modules for dual cooling.

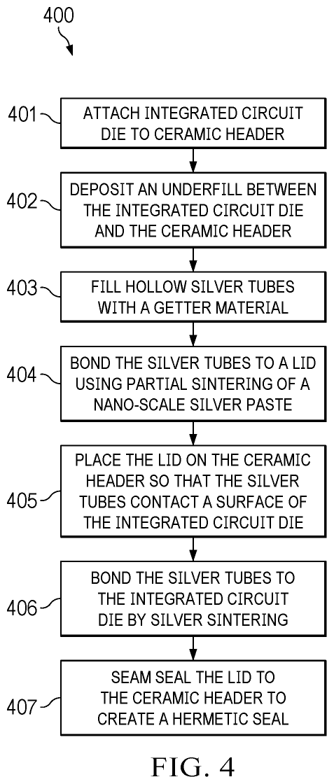

FIG. 4 is a flowchart illustrating an example process for assembling a hermetic ceramic package with dual-sided cooling using silver tubes with getter material to absorb moisture. In step 401, an integrated circuit die is attached to a ceramic header. The ceramic header has an interior cavity with an interior mounting surface. A number of landing pads are formed on the interior mounting surface. the integrated circuit die has a number of bond pads on an active surface. Conductive solder bumps are placed directly on the bond pads. The integrated circuit die is flipped so that active surface faces down. The conductive bumps contact the landing pads on the interior mounting surface. The solder bumps are reflowed to bond the integrate circuit die to the ceramic header.

In step 402, an underfill is deposited between the interior mounting surface of the ceramic header and the active surface of the integrated circuit die. The underfill may be a polymeric encapsulant in one example.

In step 403, hallow silver tubes are filled with a getter material. The getter material is designed to react with gases and moisture by adsorption, absorption, or chemical binding.

In step 404, the silver tubes are bonded to a lid using partial sintering of a nano-scale silver paste. The lid may be an iron-nickel-cobalt (FeNiCo) alloy in one example.

In step 405, the lid is placed on the ceramic header so that the silver tubes contact a surface of the integrated circuit die. A seal ring may be positioned between the ceramic header and the lid.

In step 406, the silver tubes are bonded to the integrated circuit die by silver sintering. This creates a thermal pathway with a low thermal pathway from the integrated circuit die to the lid via the silver tubes and the nano-scale silver paste.

In step 407, a seam seal is created between the lid and the ceramic header to create a hermetic seal.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A semiconductor package, comprising:
a ceramic header having a top surface and a cavity formed within the ceramic header, the cavity open at the top surface;
a semiconductor die mounted within the cavity of the ceramic header;
a lid structure coupled to the top surface of the ceramic header, the lid structure and ceramic header forming a portion of a package enclosing the semiconductor die; and
one or more silver tubes in contact with a first surface of the semiconductor die and with a first surface of the lid structure.

2. The semiconductor package of claim 1, further comprising:
a seal ring between the top surface of the ceramic header and the lid structure, the seal ring coupling the lid structure to the ceramic header.

3. The semiconductor package of claim 1, wherein the one or more silver tubes are hollow.

4. The semiconductor package of claim 3, further comprising:
a getter material disposed within the one or more hollow silver tubes.

5. The semiconductor package of claim 1, further comprising:
a first layer of nano-scale silver material bonded between the one or more silver tubes and the first surface of the lid structure.

6. The semiconductor package of claim 5, further comprising:
a second layer of nano-scale silver material bonded between the one or more silver tubes and the first surface of the semiconductor die.

7. The semiconductor package of claim 6, wherein the first layer of nano-scale silver material and the second layer of nano-scale silver material are bonded by sintering.

8. The semiconductor package of claim 1, wherein the ceramic header comprises:
a multi-layer substrate having a plurality of conductive traces coupling landing pads on an interior surface of the cavity to conductive pads on a bottom surface of the ceramic header;
a plurality of solder bumps coupling the landing pads to bond pads formed on an active surface of the semiconductor die.

9. The semiconductor package of claim 1, further comprising:
an electroplate metal layer on a second surface of the lid structure.

10. The semiconductor package of claim 1, further comprising:
a seam seal between the lid structure and the ceramic header.

11. The semiconductor package of claim 1, further comprising:
a first thermal path from the semiconductor die to a bottom surface of the package via solder bumps and the ceramic header; and
a second thermal path from the semiconductor die to a top surface of the package via the one or more silver tubes and the lid structure.

12. A semiconductor package, comprising:
a ceramic header structure having a top surface and a bottom surface, a cavity formed within the top surface of the ceramic header;
a semiconductor device attached to a mounting surface within the ceramic header cavity;
a lid coupled to the top surface of the ceramic header, the lid and ceramic header configured to enclose the semiconductor die;
one or more hollow silver tubes in contact with a first surface of the semiconductor device and with a first surface of the lid; and
a getter material disposed within the one or more hollow silver tubes.

13. The semiconductor package of claim 12, further comprising:
a seal ring between the top surface of the ceramic header and the lid, the seal ring coupling the lid to the ceramic header; and
a seam seal between the lid and the ceramic header.

14. The semiconductor package of claim 12, further comprising:
a first layer of nano-scale silver material bonded between the one or more silver tubes and the first surface of the lid; and
a second layer of nano-scale silver material bonded between the one or more silver tubes and the first surface of the semiconductor device;
wherein the first layer of nano-scale silver material and the second layer of nano-scale silver material are bonded by sintering.

15. The semiconductor package of claim 12, further comprising:
a plurality of conductive pads on the bottom surface of the ceramic header;
a plurality of solder joints coupling the conductive pads to a first printed circuit board;
an electroplate metal layer on a second surface of the lid structure; and
a solder joint coupling the electroplate metal layer of the lid structure to a second printed circuit board.

16. The semiconductor package of claim 15, further comprising:
a first thermal path from the semiconductor device to first printed circuit board via the ceramic header; and
a second thermal path from the semiconductor die to the second printed circuit board via the one or more silver tubes and the lid structure.

17. A method of manufacturing a semiconductor package, comprising:
providing a ceramic header structure having a top surface, a bottom surface, and a cavity formed within the top surface;
attaching a semiconductor die to a mounting surface within the ceramic header cavity;
sintering a plurality of silver tubes to a lid structure using a nano-scale silver material;
attaching the lid structure to the top surface of the ceramic header so that the plurality of silver tubes contact a surface of the semiconductor die; and
sintering the silver tubes to the semiconductor die surface.

18. The method of claim 17, further comprising:
attaching the lid structure to the top surface of the ceramic header using a seal ring.

19. The method of claim 17, wherein the plurality of silver tubes are hollow and are filled with a getter material.

20. The method of claim 17, wherein the semiconductor die is flip-chip mounted within the ceramic header cavity.
